(19) United States
(12) Patent Application Publication
(10) Pub. No.: US 2017/0200755 A1
(43) Pub. Date: Jul. 13, 2017

(54) Flip-Chip Image Sensor Package

(71) Applicant: OmniVision Technologies, Inc., Santa Clara, CA (US)

(72) Inventors: Chih-Hao Teng, Hsinchu City (TW); Peter Tao, Santa Clara, CA (US)

(21) Appl. No.: 14/993,554

(22) Filed: Jan. 12, 2016

(51) Int. Cl. H01L 27/146

(52) U.S. Cl. CPC H01L 27/14618; H01L 27/1462

(57) ABSTRACT

A flip-chip image-sensor package includes a substrate, a coverglass, a conductive layer, and an image sensor. The substrate has an aperture therethrough and a first region and a second region each at least partially surrounding the aperture. The aperture has a first width defined by a boundary of the first region, and a second width defined by a boundary of the second region, wherein the second width exceeds the first width. The coverglass spans the aperture and is located on a top surface of the first region. The conductive layer adjoins the substrate. The image sensor is located beneath the coverglass and is electrically connected to the conductive layer.

### BACKGROUND

Wafer-level manufacture of camera modules manufactured with complementary metal-oxide semiconductor (CMOS) technologies has contributed to the incorporation of camera modules in high-volume consumer products such as mobile devices and motor vehicles. For example, FIG. 1 shows a camera module 180 integrated into a mobile device 190. Camera module 180 includes an image sensor package (ISP) 100 beneath an imaging lens 170 optimized for use with ISP 100.

### SUMMARY OF THE INVENTION

In one embodiment, a flip-chip image-sensor package (ISP) is disclosed. The flip-chip ISP includes a substrate, a coverglass, a conductive layer, and an image sensor. The substrate has an aperture therethrough and a first region and a second region each at least partially surrounding the aperture. The aperture has a first width defined by a boundary of the first region, and a second width defined by a boundary of the second region, wherein the second width exceeds the first width. The coverglass spans the aperture and is located on a top surface of the first region. The conductive layer adjoins the substrate. The image sensor is located beneath the coverglass and is electrically connected to the conductive layer.

### BRIEF DESCRIPTION OF THE FIGURES

FIG. 1 shows a mobile device having a camera module integrated therein that includes an ISP.

FIG. 2 is a cross-sectional view of a lens aligned with a chip-on-board (COB) ISP that compatible to function as the ISP of FIG. 1.

FIG. 3 is a cross-sectional view of an exemplary flip-chip ISP.

FIG. 4 is a cross-sectional view of an exemplary flip-chip ISP, in an embodiment.

FIG. 5 is a top plan view of the flip-chip ISP of FIG. 4.

FIG. 6 shows a first transmission spectrum of an optical coating for a coverglass of the flip-chip ISP of FIG. 4, in an embodiment.

FIG. 7 shows a second transmission spectrum of an optical coating for a coverglass of the flip-chip ISP of FIG. 4, in another embodiment.

FIG. 8 shows a third transmission spectrum of an optical coating for a coverglass of the flip-chip ISP of FIG. 4, in another embodiment.

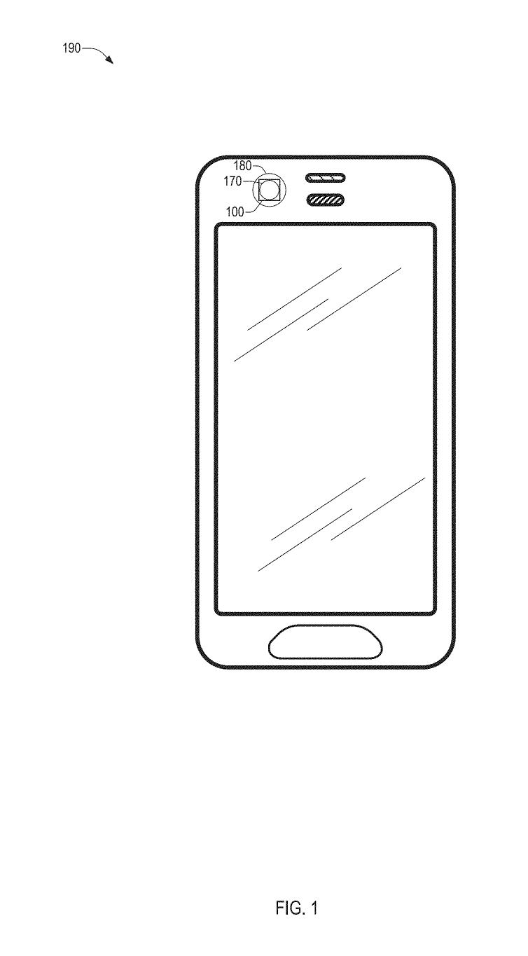

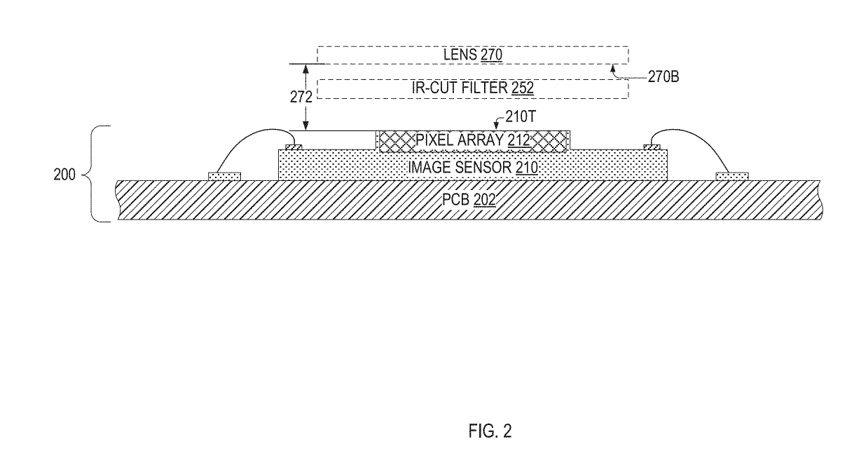

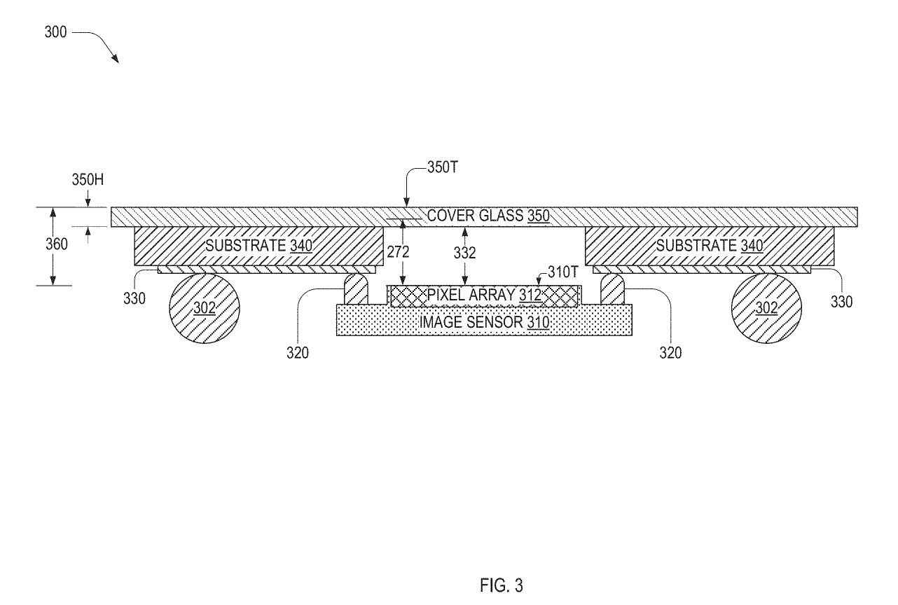

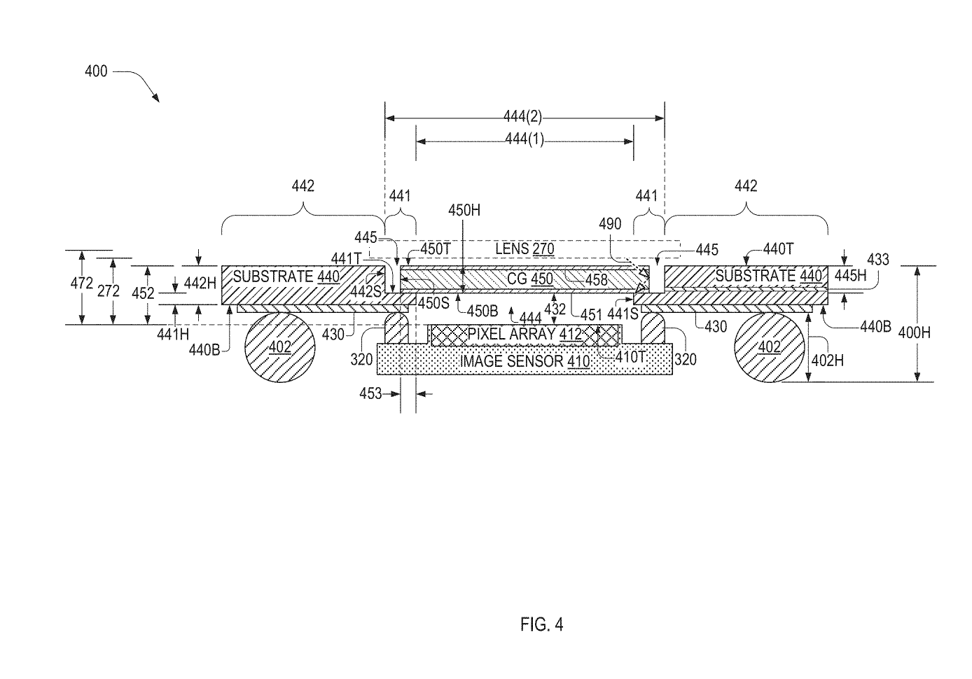

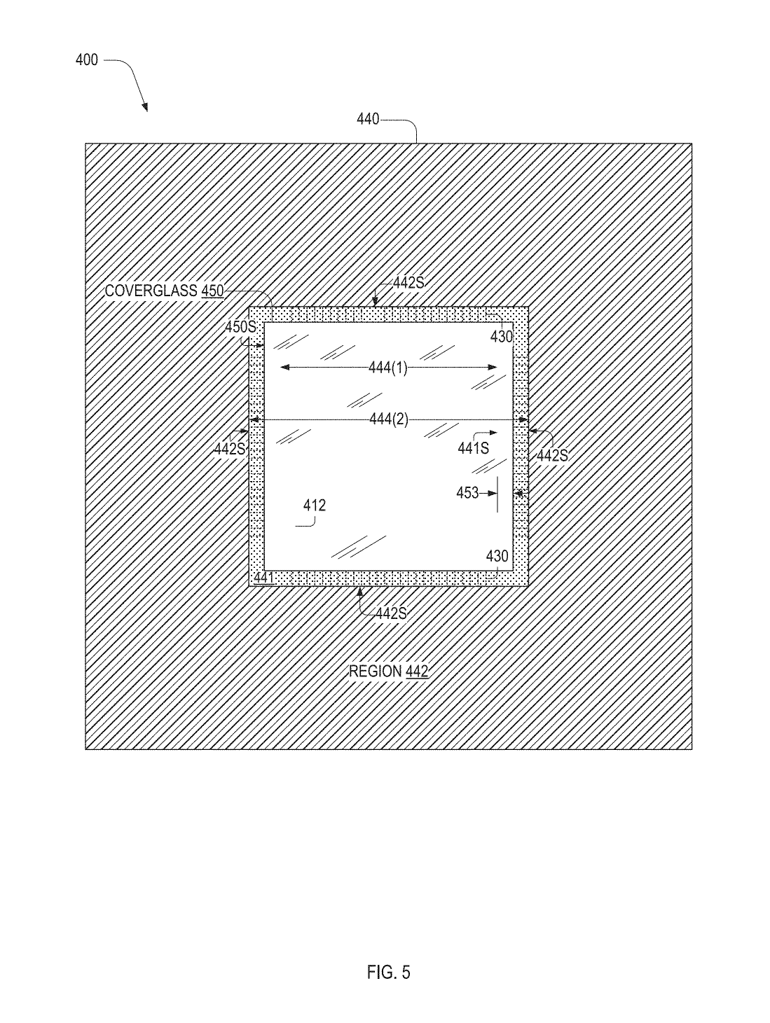

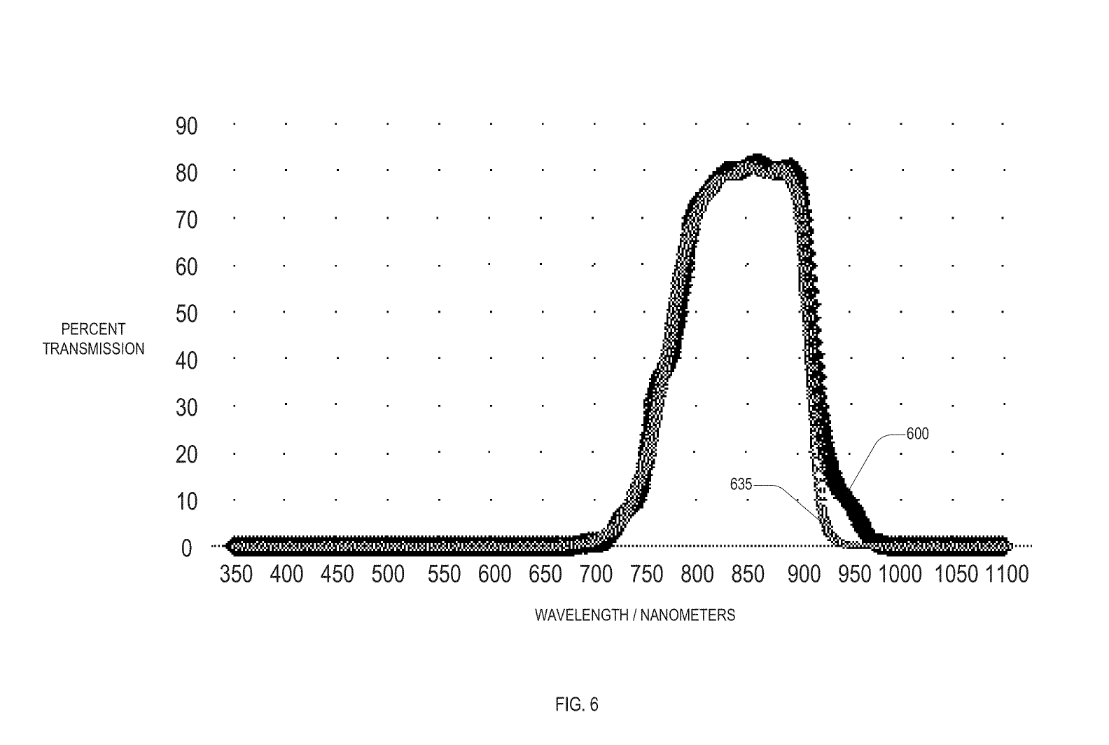

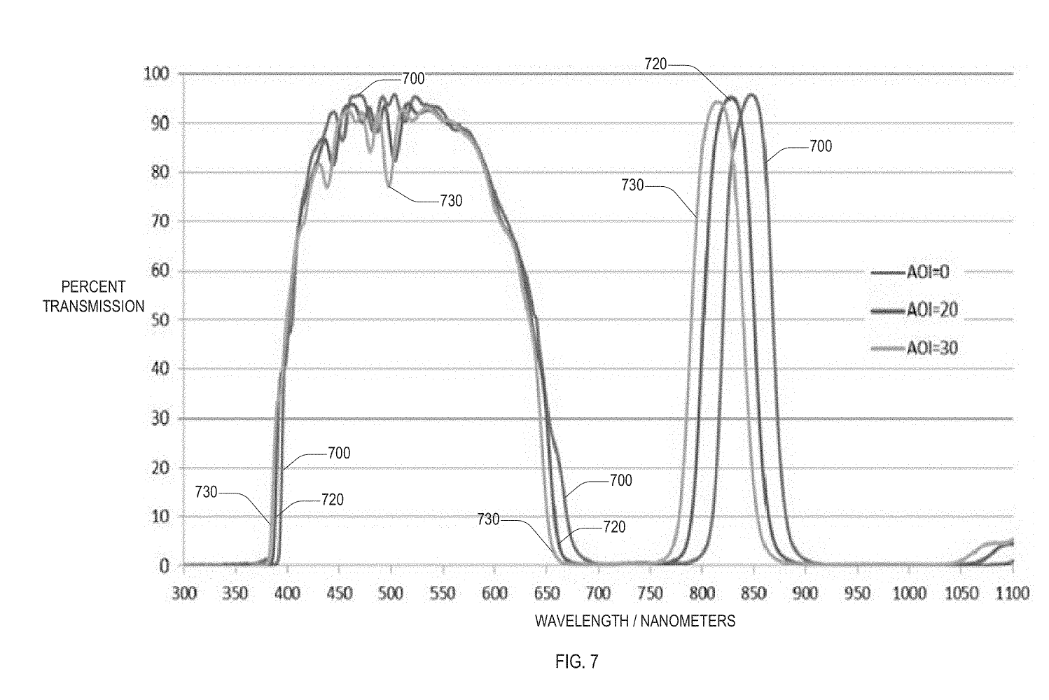

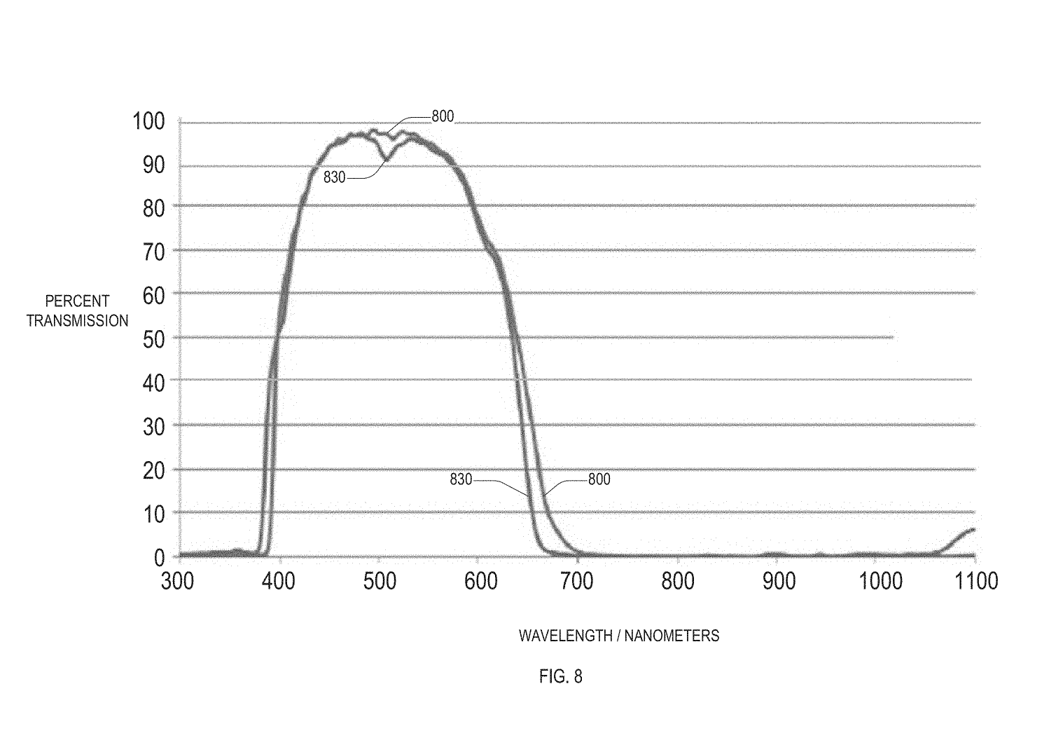

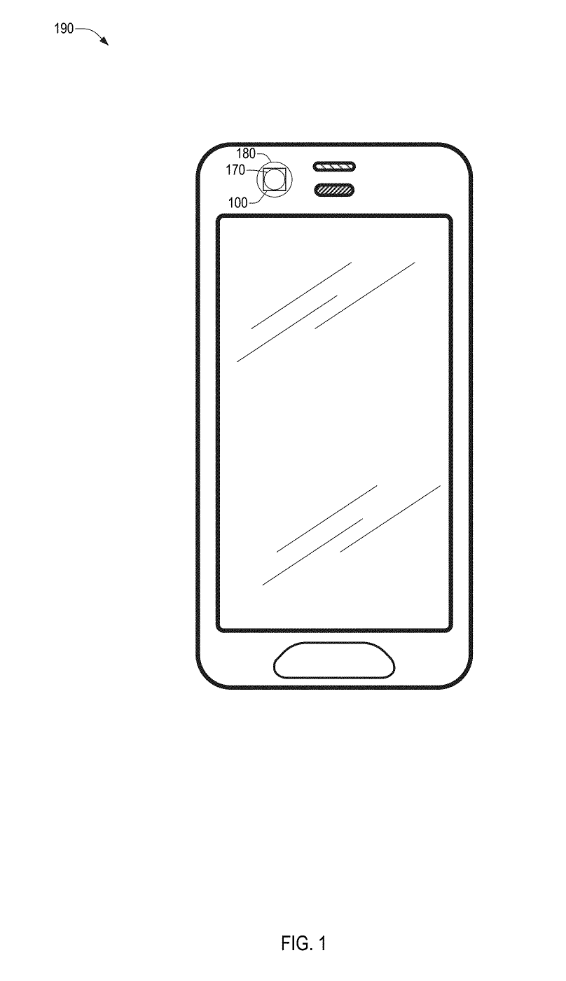

### DETAILED DESCRIPTION OF THE EMBODIMENTS

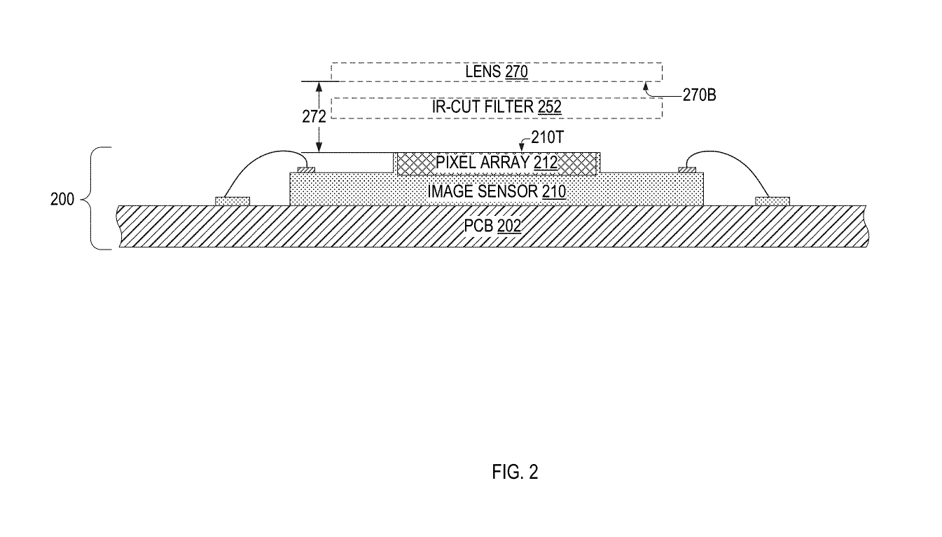

FIG. 2 is a cross-sectional view of a lens 270 aligned with a chip-on-board (COB) ISP 200 that compatible to function as ISP 100 within a camera module 180 of mobile device 190. It should be appreciated that ISP 200 may be used with any other imaging application as well, such as, but not limited to, computer cameras, hand held cameras, and automotive imaging systems. Lens 270 is an example of imaging lens 170 and is optimized for use with COB ISP 200. COB ISP 200 includes an image sensor 210 on a printed circuit board 202. Image sensor 210 has a top surface 210T and includes a pixel array 212. Optionally, an IR-cut filter 252 may be between lens 270 and COB ISP 200.

Lens 270 has a bottom surface 270B at a working distance 272 above top surface 210T. In a region beneath lens 270, the top surface of COB ISP 200 corresponds to a top surface 210T of image sensor 210. Hence, lens 270 and working distance 272 may be jointly optimized, with or without the presence of IR-cut filter 252, such that lens 270 forms an in-focus image on image sensor 210. In such an optimization, and absent any optical elements (a filter for example) between lens 270 and image sensor 210, working distance 272 has a theoretical lower limit of zero. Herein, working distance 272 may also be referred to as COB optimal working distance 272, corresponding to the height of lens 270 above image sensor 210 such that lens 270 forms an in-focus image at an image plane corresponding to top surface 210T.

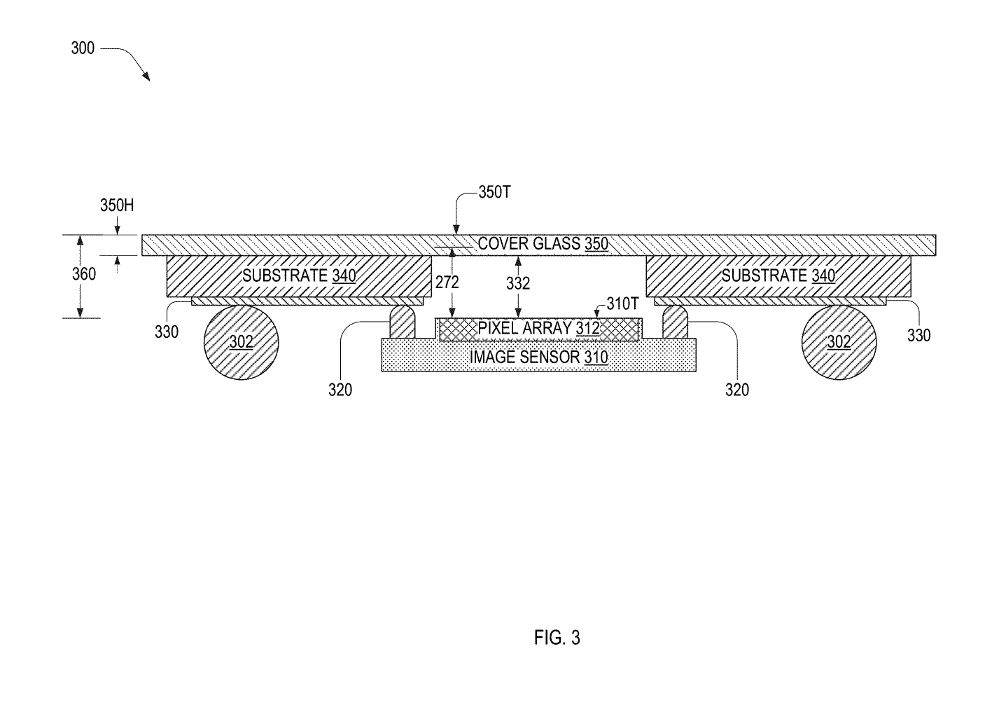

FIG. 3 is a cross-sectional view of a flip-chip ISP 300 compatible to function as ISP 100. Flip-chip ISP 300 includes an image sensor 310, conductive pads 320, conductive traces 330, a substrate 340, and a coverglass 350. Coverglass 350 has a thickness 350H and a top surface 350T. Image sensor 310 includes a pixel array 312 and has a top surface 310T. Coverglass 350 and top surface 310T are separated by a distance 332. Distance 360 between top surface 350T and image sensor 310 is the sum of distance 332 and thickness 350H. Flip-chip ISP 300 may also include a plurality of ball-grid-array balls 302.

For illustrative purposes, FIG. 3 also denotes COB optimal working distance 272 to illustrate that flip-chip ISP 300 is incompatible with lens 270. Specially, coverglass 350 imposes a lower limit (distance 360) on a lens height of an imaging lens 270 above image sensor 310. Coverglass 350 prevents lens 270 from being positioned sufficiently close to surface 310T (at optimal working distance 272), such that lens 270 cannot form an in-focus image on pixel array 312.

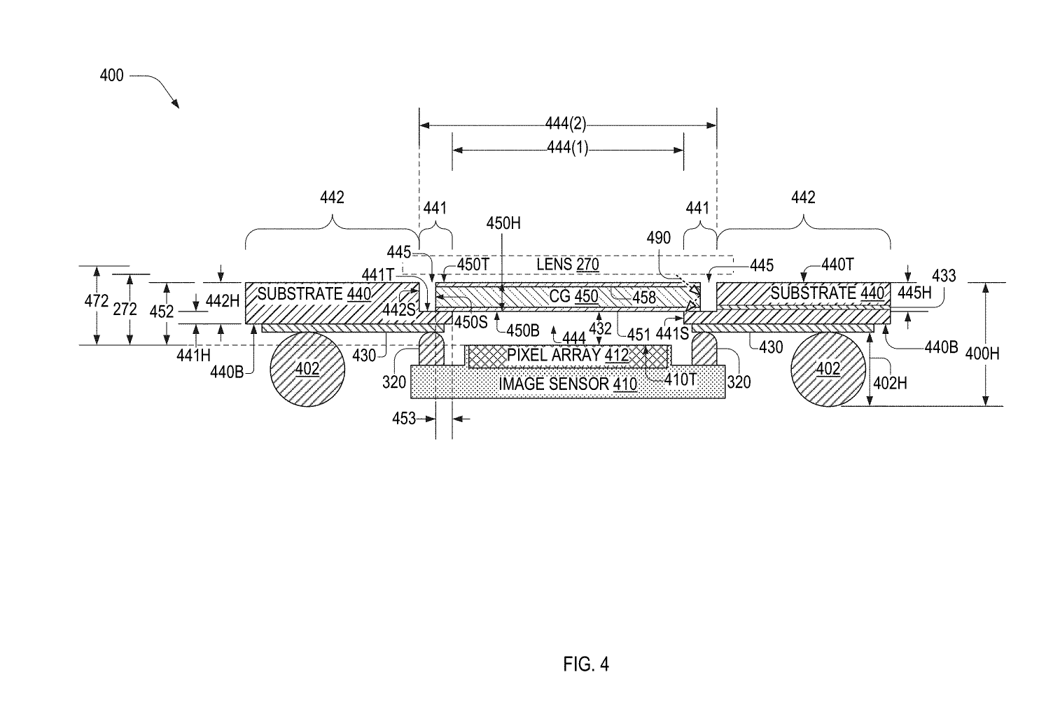

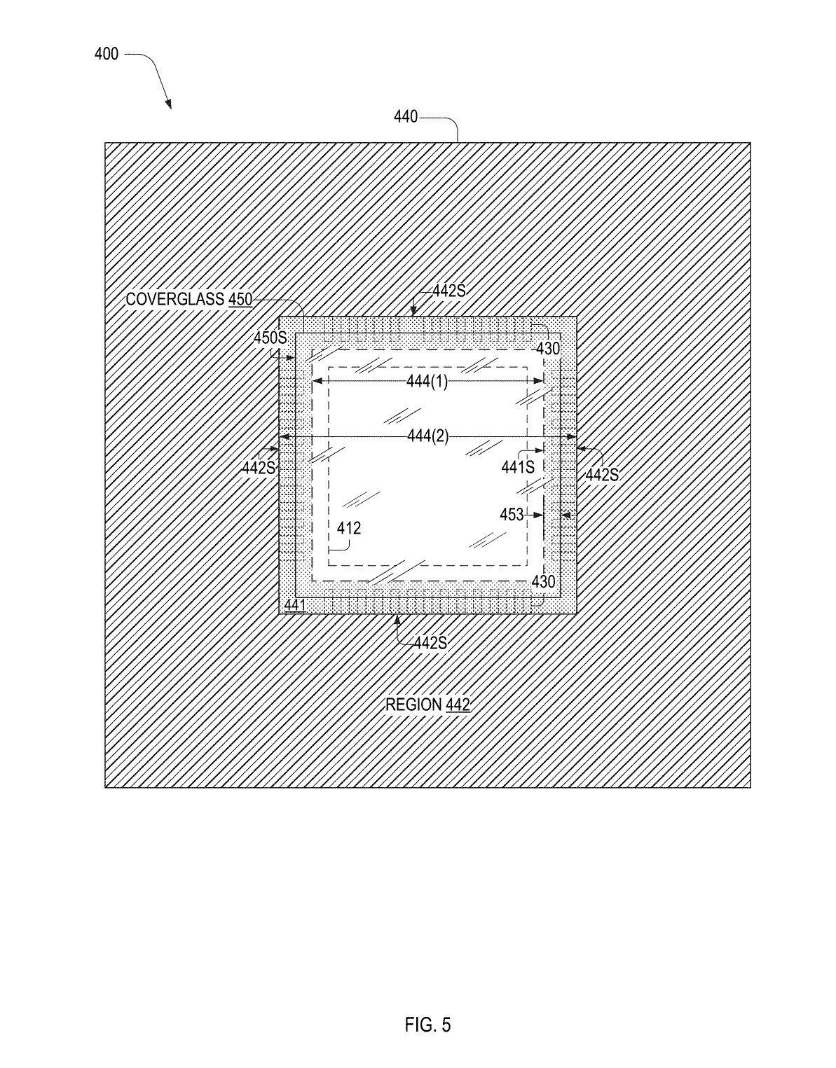

FIG. 4 is a cross-sectional view of an exemplary flip-chip ISP 400, compatible to function as ISP 100. FIG. 5 is a top plan view of flip-chip ISP 400. FIGS. 4 and 5 are best viewed together in the following discussion. Flip-chip ISP 400 includes a substrate 440, a coverglass 450, a plurality of conductive traces 430, conductive pads 320, and an image sensor 410 having a pixel array 412. Flip-chip ISP 400 may also include a plurality of ball-grid-array balls 402.

Coverglass 450 has a top surface 450T located at a distance 452 above a top surface 410T of image sensor 410. Distance 452 is less than COB optimal working distance 272 of lens 270, which makes flip-chip ISP 400 compatible with lens 270. That is, no part of flip-chip ISP 400 interferes with lens 270 being located at a distance above top surface 410T equal to or exceeding COB optimal working distance 272. For example, the refractive index of coverglass 450 (and of any coatings thereon) results in the optimal working distance of lens 270 above top surface 410T to deviate from COB optimal working distance 272 such that it equals a working distance 472, such that top surface 410T corresponds to the image plane of lens 270.

Substrate 440 has an aperture 444 therethrough, an inner region 441, an outer region 442, a top surface 440T, and a bottom surface 440B. Substrate 440 may be formed of a ceramic material, or other suitable materials known in the art. Inner region 441 at least partially surrounds aperture 444, has a first thickness 441H, and a top surface 441T. Outer region 442 at least partially surrounds the inner region 441 and has a second thickness 442H that exceeds first thickness 441H.

Inner region 441 has a surface 441S that surrounds aperture 444 and defines an inner width 444(1) thereof. Outer region 442 has a surface 442S that surrounds aperture 444 and defines an outer width 444(2) thereof. FIG. 5 illustrates aperture 444 as being square. Aperture 444 may be differently-shaped without departing from the scope hereof. In an embodiment, aperture 444 is circular such that widths 444(1) and 444(2) are inner and outer diameters, respectively, of aperture 444. The shape of aperture 444, as seen in the plan view of FIG. 5, may be polygonal, elliptical, a convex polygon, a concave polygon, any combination thereof, and most generally a Jordan curve.

Coverglass 450 is on top surface 441T and spans aperture 444 such that at least part of coverglass 450 is within recess region 445. Coverglass 450 has a bottom surface 450B, a top surface 450T, and may include at least one of a top coating 458 and a bottom coating 451. Coverglass 450 has a coverglass thickness 450H that includes thicknesses of any coatings thereon. In the embodiment shown in FIG. 4, coverglass thickness 450H is equal to a recess depth 445H, which is the difference between second thickness 442H and first thickness 441H. Coverglass thickness 450H may be greater than or less than recess depth 445H without departing from the scope hereof. Coverglass 450 is entirely within recess region 445 when recess depth 445H equals or exceeds coverglass thickness 450H.

Coverglass 450 includes a side surface 450S. FIG. 4 includes an exemplary stray light ray 490 incident on coverglass 450 at non-normal angle with respect to top surface 450T. Stray light ray 490 reflects off of side surface 450S and propagates toward pixel array 412. Absent top surface 441T of inner region 441, stray light ray 490 would be detected by pixel array 412, which would result in an image artifact. Surface 441T overlaps bottom surface 450B a distance 453 such that surface 441T functions to block stray light ray 490. Distance 453 is 0.5 mm and may vary without departing from the scope hereof. For example, distance 453 may depend on the thickness 450H of cover glass 450. Surface 441T may include an absorptive layer (not shown) for at least partially absorbing stray light ray 490, and hence minimizing its reflection off of surfaces of coverglass 450.

Conductive traces 430 are attached to bottom surface 440B. Image sensor 410 includes a pixel array 412 and is electrically connected to conductive traces 430 via conductive pads 320. In FIG. 5, pixel array 412, and the inner edge of inner region 441 are illustrated with dashed lines to indicate that they are each beneath coverglass 450 Similarly, conductive traces 430 are illustrated with dashed lines to indicate that they are each beneath substrate 440. Each of the plurality of ball-grid-array balls 402, if included, is electrically connected to a respective conductive trace 430.

In an embodiment, flip-chip ISP 400 also includes one or more conductive traces between surfaces 440B and 440T of substrate 440. For example, FIG. 4 illustrates an embedded conductive trace 433, which may be electrically connected to image sensor 410. In an embodiment, flip-chip ISP 400 lacks conductive traces 430 and embedded conductive trace 433 is one of a plurality of embedded conductive traces 433 each electrically connected to image sensor 410.

Pixel array 412 includes N pixels 412(1, 2, . . . , N). Each pixel 412(i) has a microlens for collecting light incident on the pixel. Image sensor 410 has a top surface 410T separated by a non-zero distance 432 from bottom surface 450B of coverglass 450. A coverglass in contact with top surface 410T imposes constraints to microlens design that are not present in flip-chip ISP 400 by virtue of non-zero distance 432. Distance 432 being greater than zero allows for greater design flexibility of pixel microlenses, e.g., microlens shape and height, of one or more pixels 412(1, 2, . . . , N). For example, a pixel 412(i) may have a microlens with a planar bottom surface and a convex top surface (closer to coverglass 450) that lacks radial symmetry with respect to an axis orthogonal to the planar bottom surface. Such a lens may be optimized to collect light incident on image sensor 410 with a large chief-ray angle (CRA) with respect to normal-incidence (CRA=0°) on top surface 410T. Two pixels 412(m) and 412(n) may have different heights, for example, as a result of their having respective microlenses of different heights.

Coverglass 450 may be formed of a coverglass material known in the art. Examples include borosilicate glass, D 263® M by SCHOTT Corporation, and blue filter glass that blocks near-IR light.

Flip-chip ISP 400 has a package height 400H and ball-grid-array balls 402 have a height 402H. In an embodiment, package height 400H is between 680 μm and 800 μm, distance 452 is between 400 μm and 500 μm, and height 402H is between 100 μm and 160 μm. Distance 432 is for example between 40 μm and 50 μm. Thickness 450H of coverglass 450 (including any coatings thereon) is for example between 375 μm and 425 μm.

At least one of bottom coating 451 and top coating 458 of coverglass 450 may be an anti-reflective coating, for example, a multilayer coating having a tantalum oxide layer and a silicon dioxide layer. At least one of bottom coating 451 and top coating 458 may be an infrared (IR)-cut filter (similar to IR-cut filter 252 for example), for example, a multilayer coating having a titanium dioxide and a silicon dioxide layer. Coverglass 450 may also have an absorbing layer thereon (e.g., for blocking near-IR light), located for example between bottom coating 451 and top coating 458. In a specific embodiment, top coating 458 is an anti-reflective coating and bottom coating 451 is an IR-cut filter.

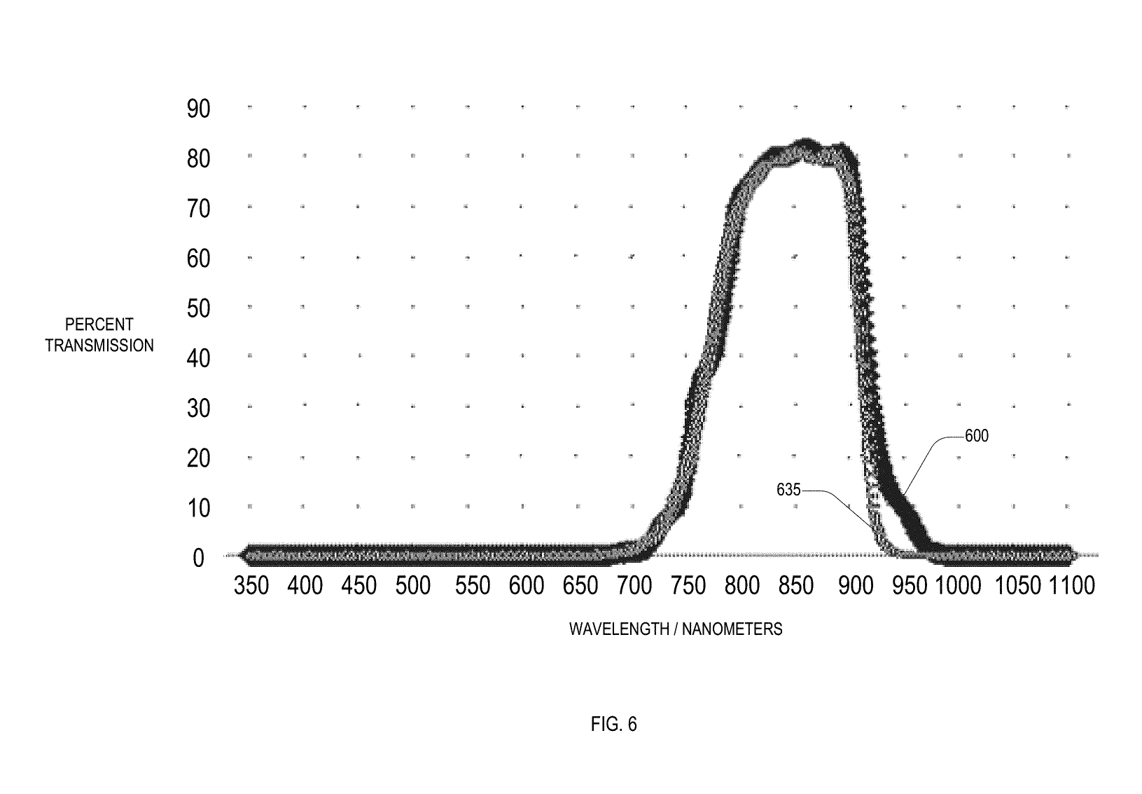

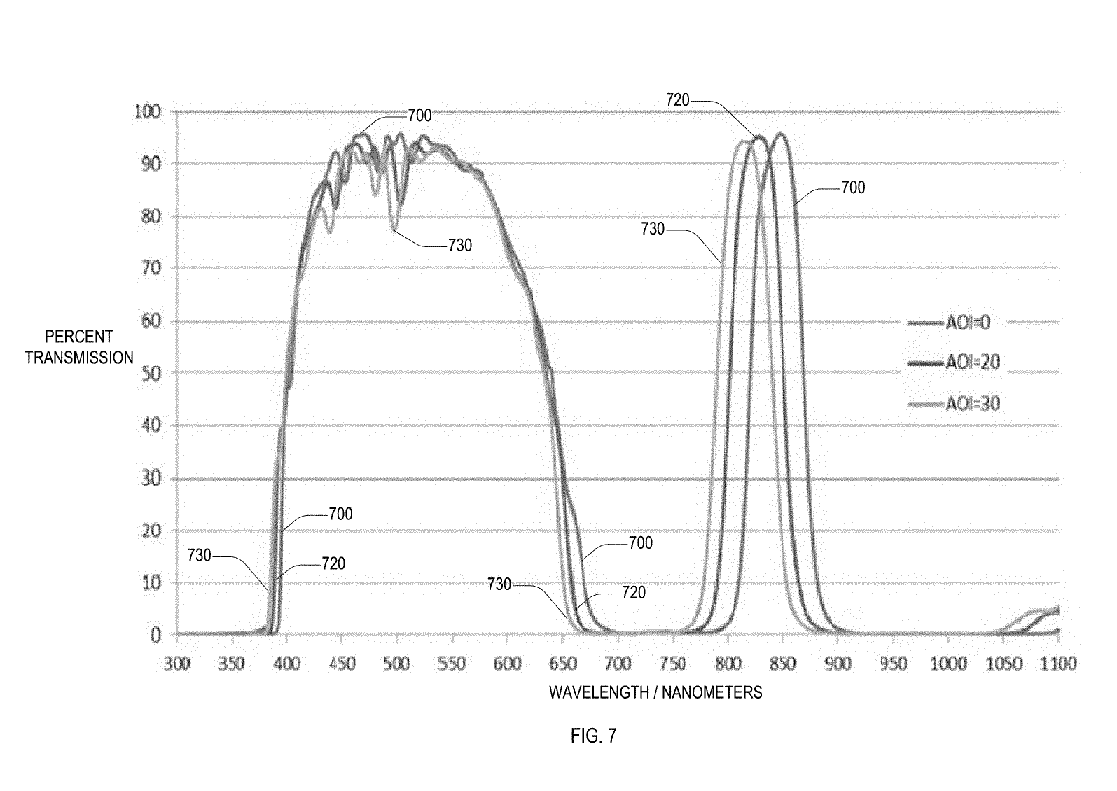

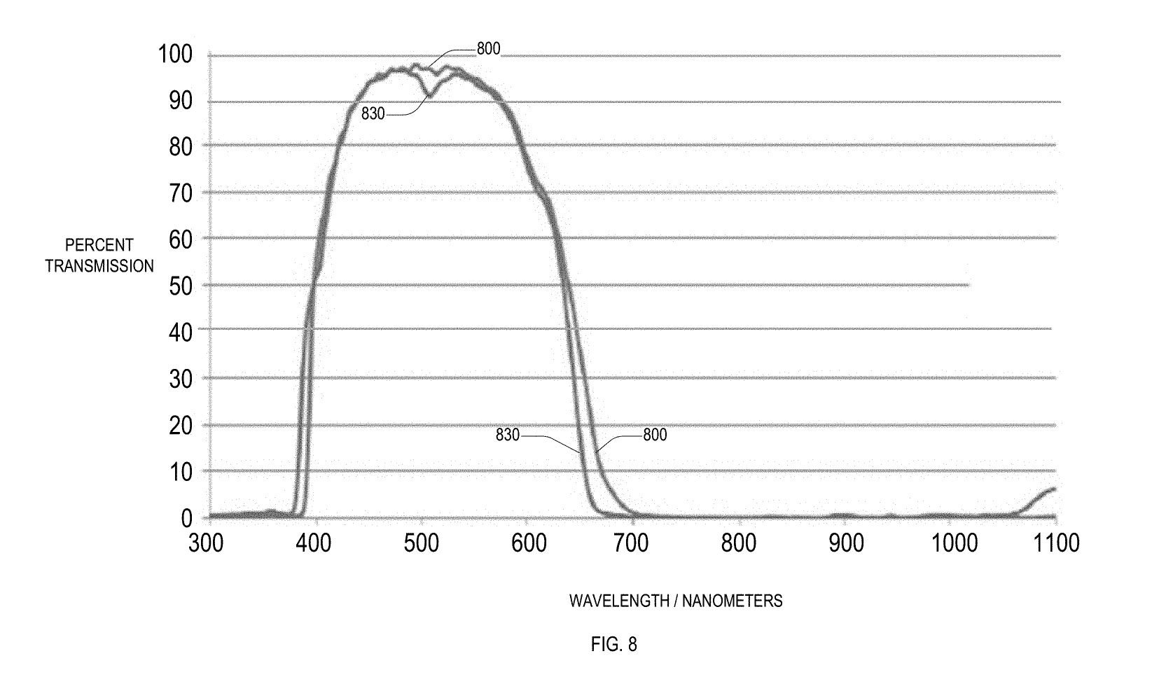

FIGS. 6-8 illustrate exemplary transmission spectra of bottom coating 451 and top coating 458. FIG. 6 is a transmission plot of a low-shift IR pass filter having transmission spectra 600 and 635 corresponding to light incident angles of zero degrees and thirty-five degrees, respectively. FIG. 7 is a transmission plot a bandpass filter having transmission spectra 700, 720, and 730 corresponding to light incident angles of zero degrees, twenty degrees, and thirty degrees, respectively. FIG. 8 is a transmission plot a bandpass filter having transmission spectra 800 and 830 corresponding to light incident angles of zero degrees and thirty degrees, respectively.

### Combinations of Features

Features described above as well as those claimed below may be combined in various ways without departing from the scope hereof. The following examples illustrate some possible, non-limiting combinations:

(A1) A flip-chip ISP includes a substrate, a coverglass, a conductive layer, and an image sensor. The substrate has an aperture therethrough and a first region and a second region each at least partially surrounding the aperture. The aperture has a first width defined by a boundary of the first region, and a second width defined by a boundary of the second region, wherein the second width exceeds the first width. The coverglass spans the aperture and is located on a top surface of the first region. The conductive layer adjoins the substrate. The image sensor is located beneath the coverglass and is electrically connected to the conductive layer.

(A2) In the flip-chip ISP denoted by (A1), at least part of the coverglass may be located within a recess region, within the substrate, formed by the interface of the top surface of the first region and a side surface of the second region, the aperture being through the recess region.

(A3) In a flip-chip ISP denoted by one of (A1) and (A2), the second region may at least partially surround the coverglass.

(A4) In a flip-chip ISP denoted by one of (A1) through (A3), the coverglass may have a thickness that is at most a thickness difference between the second region and the first region.

(A5) In a flip-chip ISP denoted by one of (A1) through (A4), the second region may be thicker than the first region

(A6) In a flip-chip ISP denoted by one of (A1) through (A5), the first region having a first bottom surface, the second region may have a second bottom surface that is coplanar with the first bottom surface

(A7) In a flip-chip ISP denoted by one of (A1) through (A6), the substrate having a bottom surface proximate the image sensor and in a bottom plane, the second region having a top surface opposite the bottom surface and in a top plane, the entirety of the coverglass may be between the bottom plane and the top plane.

(A8) In a flip-chip ISP denoted by one of (A1) through (A7), the coverglass and the image sensor may be spatially separated by at least a thickness of the first region.

(A9) In a flip-chip ISP denoted by one of (A1) through (A8), the image sensor may have a plurality of pixels with differing heights.

(A10) In a flip-chip ISP denoted by one of (A1) through (A9), the substrate having a bottom surface proximate the image sensor and in a bottom plane, the second region having a top surface opposite the bottom surface and in a top plane, a conductive trace may be between the bottom plane and the top plane

(A11) In a flip-chip ISP denoted by one of (A1) through (A10), the coverglass may have at least one of (i) a bottom coating on a bottom surface of the coverglass proximate the image sensor and (ii) a top coating on a top surface of the coverglass opposite the image sensor.

(A12) In the flip-chip ISP denoted by one (A11), at least one of the bottom coating and the top coating may be an IR-cut filter.

(A13) In a flip-chip ISP denoted by one of (A12) through (A13), at least one of the bottom coating and the top coating may be an anti-reflective coating.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

1. A flip-chip image-sensor package (ISP) comprising:
a substrate having
an aperture therethrough, and
a first region and a second region each at least partially surrounding the aperture,
the aperture having a first width defined by a boundary of the first region, and a second width defined by a boundary of the second region, the second width exceeding the first width,
a recess region, within the substrate, bounded by a top surface of the first region and a side surface of the second region having at most one non-conductive layer, the aperture being through the recess region,
a coverglass spanning the aperture and on a top surface of the first region, and being located at least partially within a recess region;
a conductive layer adjoining the substrate; and
an image sensor beneath the coverglass and electrically connected to the conductive layer.

2. (canceled)

3. The flip-chip ISP of claim 1, the second region at least partially surrounding the coverglass.

4. The flip-chip ISP of claim 1, the coverglass having a thickness that is at most a thickness difference between the second region and the first region.

5. The flip-chip ISP of claim 1, the second region being thicker than the first region.

6. The flip-chip ISP of claim 1, the first region having a first bottom surface, the second region having a second bottom surface that is coplanar with the first bottom surface.

7. The flip-chip ISP of claim 1, the substrate having a bottom surface proximate the image sensor and in a bottom plane, the second region having a top surface opposite the bottom surface and in a top plane, the entirety of the coverglass being between the bottom plane and the top plane.

8. The flip-chip ISP of claim 1, the coverglass and the image sensor being spatially separated by at least a thickness of the first region.

9. The flip-chip ISP of claim 1, the image sensor having a plurality of pixels with differing heights.

10. The flip-chip ISP of claim 1, the substrate having a bottom surface proximate the image sensor and in a bottom plane, the second region having a top surface opposite the bottom surface and in a top plane, and a conductive trace being between the bottom plane and the top plane.

11. The flip-chip ISP of claim 1, the coverglass having at least one of (i) a bottom coating on a bottom surface of the coverglass proximate the image sensor and (ii) a top coating on a top surface of the coverglass opposite the image sensor.

12. The flip-chip ISP of claim 11, at least one of the bottom coating and the top coating being an IR-cut filter.

13. The flip-chip ISP of claim 11, at least one of the bottom coating and the top coating being an anti-reflective coating.
